(19) United States
(12) Patent Application Publication
(10) Pub. No.: US 2026/0068160 A1
(43) Pub. Date: Mar. 5, 2026

(54) SEMICONDUCTOR DEVICE INCLUDING A CHIP GUARD

(71) Applicant: SK hynix Inc., Icheon-si Gyeonggi-do (KR)

(72) Inventor: Jeong Yun LEE, Icheon-si Gyeonggi-do (KR)

(73) Assignee: SK hynix Inc., Icheon-si Gyeonggi-do (KR)

(21) Appl. No.: 19/081,938

(22) Filed: Mar. 17, 2025

(30) Foreign Application Priority Data
Aug. 27, 2024 (KR) 10-2024-0115091

(51) Int. Cl. H10B 43/27; H01L 23/00; H10B 41/27; H10B 41/30; H10B 41/40; H10B 43/30; H10B 43/40

(52) U.S. Cl. CPC H10B 43/27; H10B 41/27; H10B 41/30; H10B 41/40; H10B 43/30; H10B 43/40

(57) ABSTRACT

A semiconductor device includes a substrate. The semiconductor device also includes a first conductive chip guard pattern over a chip guard region of the substrate. The semiconductor device further includes a second conductive chip guard pattern over the first conductive chip guard pattern. The semiconductor device additionally includes a buffer layer between the first and second conductive chip guard patterns.

### CROSS-REFERENCE TO RELATED APPLICATION

The present application claims priority under 35 U.S.C. § 119(a) to Korean patent application number 10-2024-0115091, filed on Aug. 27, 2024, in the Korean Intellectual Property Office, the entire disclosure of which application is incorporated herein by reference.

### BACKGROUND

### 1. Technical Field

Various embodiments of the present disclosure generally relate to a semiconductor device, and more particularly, to a semiconductor device including a chip guard.

### 2. Related Art

A semiconductor device includes multilayered patterns that form an integrated circuit. In a plan view, the integrated circuit is enclosed by a chip guard region. A chip guard is formed in the chip guard region to protect the integrated circuit from stress or moisture that is generated during a dicing process or the like.

As the integrated circuit becomes larger in capacity and more highly integrated, the height of the chip guard increases and defects of the semiconductor device due to chip guard cracks increase.

### SUMMARY

A semiconductor device according to an embodiment of the present disclosure may include a substrate; an integrated circuit over an integrated circuit region of the substrate; a first conductive chip guard pattern over a chip guard region of the substrate, wherein the integrated circuit region is enclosed by the chip guard region; a second conductive chip guard pattern over the first conductive chip guard pattern; and a buffer layer between the first conductive chip guard pattern and the second conductive chip guard pattern.

A semiconductor device according to an embodiment of the present disclosure may include a substrate; a source structure over a cell array region of the substrate; a channel structure extending from the source structure in a vertical direction over the cell array region of the substrate; a gate stacked body including a plurality of interlayer insulating layers and a plurality of conductive layers alternately stacked over the source structure, the channel structure extending through the gate stacked body in the vertical direction; a first conductive chip guard pattern over a chip guard region of the substrate, wherein the first conductive chip guard pattern and the source structure are at a same vertical level, wherein the chip guard region encloses an integrated circuit region of the substrate, and wherein the integrated circuit region includes the cell array region and peripheral circuit region of the substrate; a second conductive chip guard pattern over the first conductive chip guard pattern, wherein the second conductive chip guard pattern and the gate stacked body are at the same vertical level; and a buffer layer between the first conductive chip guard pattern and the second conductive chip guard pattern.

### BRIEF DESCRIPTION OF THE DRAWINGS

FIG. 1 is a plan view illustrating a substrate of a semiconductor device according to an embodiment of the present disclosure.

FIGS. 2A and 2B are sectional views illustrating a semiconductor device according to an embodiment of the present disclosure.

FIG. 3 is a sectional view illustrating a peripheral contact structure and a signal line according to an embodiment of the present disclosure.

FIGS. 4A, 4B, and 4C are sectional views illustrating chip guards according to embodiments of the present disclosure.

FIGS. 5A, 5B, and 5C are sectional views illustrating a preliminary source stacked body and a lower insulating layer according to an embodiment of the present disclosure.

FIGS. 6A and 6B are sectional views illustrating a conductive penetration structure of a first group and a buffer layer according to an embodiment of the present disclosure.

FIG. 7 is a sectional view illustrating a dummy pattern and a buffer pattern of a buffer layer according to an embodiment of the present disclosure.

FIGS. 8A to 8I are sectional views illustrating a stacked body, a conductive penetration structure of a second group, a memory layer, a channel structure, a slit, a source structure, a gate stacked body, a vertical structure, and a conductive penetration structure of a third group according to an embodiment of the present disclosure.

FIG. 9 is a sectional view illustrating a buffer layer, a first conductive chip guard pattern, and a second conductive chip guard pattern according to an embodiment of the present disclosure.

FIG. 10 is a sectional view illustrating a buffer layer according to an embodiment of the present disclosure.

FIGS. 11A and 11B are sectional views illustrating a sidewall buffer pattern and a conductive penetration structure of a first group according to an embodiment of the present disclosure.

FIGS. 12A and 12B are sectional views illustrating a conductive penetration structure of a first group and a buffer pattern according to an embodiment of the present disclosure.

FIG. 13 is a block diagram illustrating an electronic system according to an embodiment of the present disclosure.

### DETAILED DESCRIPTION

Specific structural or functional descriptions of embodiments according to the concept of the present disclosure, disclosed in the present specification or application, are exemplified to describe the embodiments according to the concept of the present disclosure. The embodiments according to the concept of the present disclosure are not to be construed as being limited to embodiments described in the present specification or application, and they may be variously modified and replaced with other equivalent embodiments.

It will be understood that, although the terms “first,” “second,” etc. may be used herein to describe various elements, these elements should not be limited by these terms. These terms are only used to distinguish one element from another element, and the order or number of components is not limited by the terms. In addition, it is not construed as limiting the number of components unless there is a special limitation on components expressed in singular or plural numbers. It will be understood that when an element or layer etc., is referred to as being “on,” “connected to,” or “coupled to” another element or layer etc., it can be directly on, connected or coupled to the other element or layer etc., or intervening elements or layers etc., may be present. In contrast, when an element or layer etc., is referred to as being “directly on,” “directly connected to,” or “directly coupled to” another element or layer etc., there are no intervening elements or layers etc., present.

Various embodiments of the present disclosure are directed to a semiconductor device capable of improving the stability of a manufacturing process and structural stability.

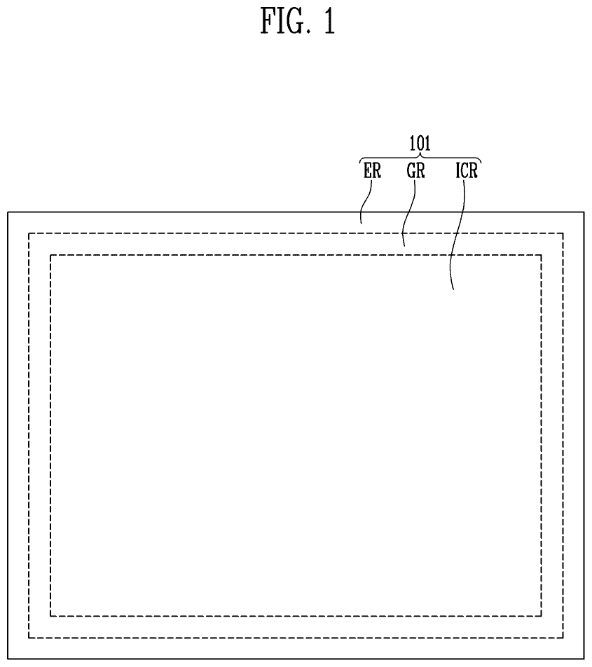

FIG. 1 is a plan view illustrating a substrate of a semiconductor device according to an embodiment of the present disclosure.

Referring to FIG. 1, the semiconductor device includes a substrate 101. The substrate 101 may include a monocrystalline semiconductor substrate. In an embodiment, the substrate 101 may include a monocrystalline silicon substrate. The substrate 101 may include an integrated circuit region ICR, a chip guard region GR, and an edge region ER. In a plan view, the chip guard region GR may enclose the integrated circuit region ICR, and the edge region ER may enclose the chip guard region GR.

The integrated circuit of the semiconductor device may be in the integrated circuit region ICR. The integrated circuit may form a semiconductor chip for a memory device, such as a flash memory device, a Magnetic Random-Access Memory (MRAM) device, a Ferroelectric Random-Access Memory (FRAM) device, a Resistive Random-Access Memory (ReRAM) device, a Phase-change Random-Access Memory (PRMA) device, a Dynamic Random-Access Memory (DRAM) device, or a Static Random-Access Memory (SRAM) device. In an embodiment, the integrated circuit may include a memory circuit that constitutes a memory cell array of the memory device, may include a logic circuit that controls the operation of the memory cell array, or may include a memory circuit and a logic circuit.

In the process of manufacturing the semiconductor device, a plurality of semiconductor chips may be formed over the substrate 101, and the plurality of semiconductor chips may be separated into chip units by performing a cutting process, such as a dicing process. The cutting process may be performed along a scribe lane region between neighboring semiconductor chips, and the edge region ER may be a portion of the scribe lane region remaining between the cutting line and the chip guard region GR.

A chip guard is formed in the chip guard region GR. The chip guard may protect the integrated circuit from stress or moisture generated in the cutting process. The chip guard may be formed of a stacked body of a plurality of conductive chip guard patterns. Each conductive chip guard pattern may be formed in a loop shape surrounding the integrated circuit region ICR along the chip guard region GR, or may be formed of a plurality of sub-patterns spaced apart from each other along the chip guard region GR.

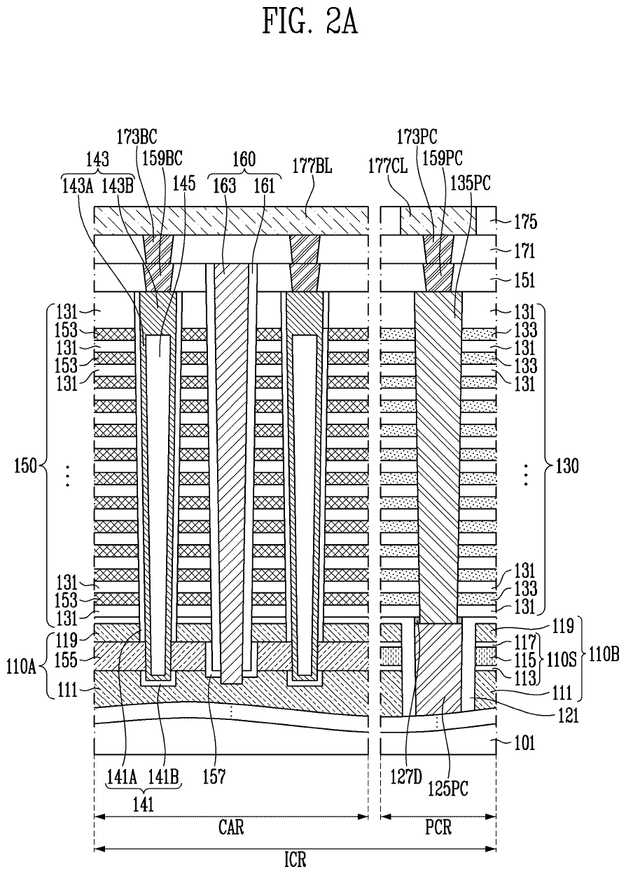

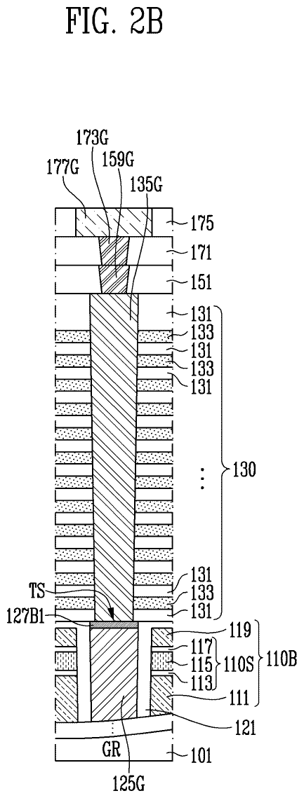

FIGS. 2A and 2B are sectional views illustrating the semiconductor device according to an embodiment of the present disclosure. FIG. 2A is a sectional view illustrating a memory cell array and a peripheral contact structure disposed over the integrated circuit region ICR of the substrate 101 illustrated in FIG. 1, and FIG. 2B is a sectional view illustrating a chip guard disposed over the chip guard region GR of the substrate 101 illustrated in FIG. 1.

Referring to FIG. 2A, the integrated circuit region ICR may include a cell array region CAR and a peripheral circuit contact region PCR.

A source structure 110A, a bit line 177BL, and a memory cell array electrically connected to the source structure 110A and the bit line 177BL may be disposed over the cell array region CAR of the substrate 101. The bit line 177BL may be vertically spaced apart from the source structure 110A. The memory cell array may be disposed between the source structure 110A and the bit line 177BL. In an embodiment, the memory cell array may form a 3D memory cell array of a NAND flash memory device. To this end, the memory cell array may include a channel structure 143 vertically extending from the source structure 110A toward the bit line 177BL, a plurality of conductive layers 153 arranged along the sidewall of the channel structure 143 to be vertically spaced apart from each other, and a memory layer 141 disposed between each of the plurality of conductive layers 153 and the channel structure 143.

The source structure 110A may include at least one doped semiconductor layer. In an embodiment, the source structure 110A may include a first doped semiconductor layer 111 over the substrate 101, a second doped semiconductor layer 119 over the first doped semiconductor layer 111, and a third doped semiconductor layer 155 disposed between the first doped semiconductor layer 111 and the second doped semiconductor layer 119. The source structure 110A contains conductive impurities. The conductive impurities may include n-type impurities, p-type impurities, or a mixture thereof. In an embodiment, each of the first doped semiconductor layer 111, the second doped semiconductor layer 119, and the third doped semiconductor layer 155 may include n-type impurities as a majority carrier. Embodiments of the present disclosure, however, are not limited thereto. In an embodiment, the source structure 110A may include an n-type impurity region including n-type impurities as the majority carrier and a p-type impurity region including p-type impurities as the majority carrier. For example, the third doped semiconductor layer 155 may form the n-type impurity region, and one or both of the first doped semiconductor layer 111 and the second doped semiconductor layer 119 may form the p-type impurity region.

The plurality of conductive layers 153 may be vertically spaced apart from the source structure 110A and may form a gate stacked body 150. The plurality of conductive layers 153 may be used as a source select line, a drain select line, and a plurality of word lines of the NAND flash memory device. In an embodiment, among the plurality of conductive layers 153, at least one layer adjacent to the source structure 110A may be used as a source select line, at least one layer adjacent to the bit line 177BL may be used as a drain select line, and the rest may be used as a plurality of word lines. Each conductive layer 153 may include one or more of various conductive materials, such as a doped semiconductor layer or a metal layer. The doped semiconductor layer may include a doped silicon layer. The metal layer may include tungsten, copper, molybdenum, etc. Each conductive layer 153 may further include a metal nitride layer. The metal nitride layer may include titanium nitride, tantalum nitride, molybdenum nitride, etc.

The gate stacked body 150 may further include a plurality of interlayer insulating layers 131 that are alternately arranged with the plurality of conductive layers 153 in a vertical direction. Each interlayer insulating layer 131 may include an insulating material, such as a silicon oxide layer or a silicon oxynitride layer.

The channel structure 143 is formed of a semiconductor material that may be used as a channel region of a memory cell string. The semiconductor material may include silicon (Si), germanium (Ge), or a mixture thereof. The channel structure 143 may have various shapes. In an embodiment, a core insulating layer 145 may be in a central region of the channel structure 143, and the channel structure 143 may include a channel portion 143A and a capping portion 143B. The channel portion 143A may be interposed between the core insulating layer 145 and the gate stacked body 150, and the capping portion 143B may extend from the channel portion 143A to cover a surface of the core insulating layer 145 facing the bit line 177BL.

The memory layer 141 includes a tunnel insulating layer, a data storage layer, and a blocking insulating layer. The tunnel insulating layer of the memory layer 141 may extend along an outer wall of the channel structure 143, and may include an insulating material, such as a silicon oxide layer. The data storage layer of the memory layer 141 may be interposed between the gate stacked body 150 and the tunnel insulating layer. In an embodiment, the data storage layer of the memory layer 141 may continuously extend in a vertical direction to be interposed between the channel structure 143 and each of the plurality of conductive layers 153 and the plurality of interlayer insulating layers 131. For example, the data storage layer may have one side continuously extending along sidewalls of the plurality of conductive layers 153 and sidewalls of the plurality of interlayer insulating layers 131, and the other side continuously extending along a sidewall of the channel structure 143. The present disclosure is not limited thereto. In an embodiment, the data storage layer of the memory layer 141 may be separated into a plurality of data storage patterns that are vertically spaced apart from each other. Each data storage pattern may be disposed between a corresponding conductive layer 153 and the channel structure 143. The data storage layer may be formed of a material layer that may store changed data using Fowler-Nordheim tunneling. In an embodiment, the data storage layer may be formed of a charge trap insulating layer, a floating gate layer, or an insulating layer including conductive nanodots. The charge trap insulating layer may include a silicon nitride layer. The blocking insulating layer of the memory layer 141 is interposed between the gate stacked body 150 and the data storage layer. The blocking insulating layer may be formed of a silicon dioxide layer, a high-k dielectric layer having a higher dielectric constant than that of the silicon dioxide layer, or a structure where the silicon dioxide layer and the high-k dielectric layer are mixed. The high-k dielectric layer may include an aluminum oxide layer, a hafnium oxide layer, or the like.

The memory layer 141 may be separated into a first memory pattern 141A and a second memory pattern 141B by the third doped semiconductor layer 155. The first memory pattern 141A may be interposed between the channel structure 143 and the gate stacked body 150, and may extend between the channel structure 143 and the second doped semiconductor layer 119. The second memory pattern 141B may be interposed between the channel structure 143 and the first doped semiconductor layer 111.

The channel structure 143 may penetrate through the gate stacked body 150 and the second doped semiconductor layer 119, and may extend into the first doped semiconductor layer 111. The channel structure 143 is electrically connected to the source structure 110A. In an embodiment, the third doped semiconductor layer 155 of the source structure 110A may penetrate through the memory layer 141, and may directly contact the channel structure 143.

A portion of the channel structure 143 adjacent to the third doped semiconductor layer 155 and the capping portion 143B of the channel structure 143 may be formed as an n-type doped region containing n-type impurities as the majority carrier.

At least one insulating layer is disposed between the gate stacked body 150 and the bit line 177BL. In an embodiment, a first insulating layer 151 and a second insulating layer 171 may be disposed between the gate stacked body 150 and the bit line 177BL. The gate stacked body 150 and the channel structure 143 may be covered with the first insulating layer 151. The first insulating layer 151 may be covered with the second insulating layer 171. The bit line 177BL may penetrate through a third insulating layer 175 on the second insulating layer 171, and may include various conductive materials, such as metal. The bit line 177B may be electrically connected to the channel structure 143 by a bit line connecting structure. The bit line connecting structure may include at least one conductive via structure. In an embodiment, the bit line connecting structure may include a first conductive via structure 159BC penetrating through the first insulating layer 151 and a second conductive via structure 173BC penetrating through the second insulating layer 171. The first conductive via structure 159BC may be coupled to the capping portion 143B of the channel structure 143, and the second conductive via structure 173BC may interconnect the first conductive via structure 159BC and the bit line 177BL.

The gate stacked body 150 may be partitioned by a vertical structure 160. In an embodiment, the vertical structure 160 may extend vertically from the source structure 110A to penetrate through the first insulating layer 151. The vertical structure 160 may include an insulating material. In an embodiment, the vertical structure 160 may include a sidewall insulating layer 161 extending along a sidewall of the gate stacked body 150 and a core pattern 163 in the central region of the vertical structure 160. The core pattern 163 may be formed of a conductive layer, such as a metal layer, a semiconductor layer, or a structure where the metal and the semiconductor are mixed. The sidewall insulating layer 161 may extend along the sidewall of each of the second doped semiconductor layer 119 and the third doped semiconductor layer 155. The core pattern 163 may contact the first doped semiconductor layer 111 of the source structure 110A. In another embodiment, the vertical structure 160 may be formed of only an insulating material.

The semiconductor device may further include a passivation layer 157 interposed between the vertical structure 160 and the third doped semiconductor layer 155. The passivation layer 157 may include an oxide layer and may extend between the first doped semiconductor layer 111 and the sidewall insulating layer 161.

A plurality of conductive contact structures 125PC, 135PC, 159PC, and 173PC forming the peripheral contact structure and a signal line 177CL may be disposed over the peripheral circuit contact region PCR of the substrate 101. The plurality of conductive contact structures 125PC, 135PC, 159PC, and 173PC may include a first conductive contact structure 125PC, a second conductive contact structure 135PC, a third conductive contact structure 159PC, and a fourth conductive contact structure 173PC, which are vertically arranged. The signal line 177CL may be disposed on substantially the same vertical level as the bit line 177BL and may be coupled to the fourth conductive contact structure 173PC.

Referring to FIG. 2B, a plurality of conductive chip guard patterns 125G, 135G, 159G, and 177G forming a chip guard may be disposed on the chip guard region GR of the substrate 101. The plurality of conductive chip guard patterns 125G, 135G, 159G, and 177G may include a first conductive chip guard pattern 125G, a second conductive chip guard pattern 135G, contact level conductive chip guard patterns 159G and 173G, and a bit line level conductive chip guard pattern 177G, which are vertically arranged. The contact level conductive chip guard patterns 159G and 173G may be disposed between the second conductive chip guard pattern 135G and the bit line level conductive chip guard pattern 177G. The number of contact level conductive chip guard patterns disposed between the second conductive chip guard pattern 135G and the bit line level conductive chip guard pattern 177G is not limited to two as illustrated in FIG. 2B. In an embodiment, the contact level conductive chip guard pattern disposed between the second conductive chip guard pattern 135G and the bit line level conductive chip guard pattern 177G may be formed of one body.

Referring to FIGS. 2A and 2B, each of the plurality of conductive contact structures 125PC, 135PC, 159PC, and 173PC, the signal line 177CL, and the plurality of conductive chip guard patterns 125G, 135G, 159G, and 177G may include a metal layer. Each of the plurality of conductive contact structures 125PC, 135PC, 159PC, and 173PC, the signal line 177CL, and the plurality of conductive chip guard patterns 125G, 135G, 159G, and 177G may further include a metal barrier layer extending along the surface of the metal layer.

The first conductive contact structure 125PC and the first conductive chip guard pattern 125G may be disposed on substantially the same vertical level as the source structure 110A. The second conductive contact structure 135PC and the second conductive chip guard pattern 135G may be disposed on substantially the same vertical level as the gate stacked body 150. Each of the second conductive contact structure 135PC and the second conductive chip guard pattern 135G may be longer in the vertical direction as compared to each of the first conductive contact structure 125PC and the first conductive chip guard pattern 125G.

A buffer layer may be disposed on a top surface of each of the first conductive contact structure 125PC and the first conductive chip guard pattern 125G. The second conductive contact structure 135PC may penetrate through the buffer layer on the first conductive contact structure 125PC to contact the first conductive contact structure 125PC, and the second conductive chip guard pattern 135G may vertically overlap the first conductive chip guard pattern 125G with the buffer layer on the first conductive chip guard pattern 125G interposed therebetween. The buffer layer may include a dummy pattern 127D enclosing the sidewall of the second conductive contact structure 135PC and a buffer pattern 127B1 disposed between the first conductive chip guard pattern 125G and the second conductive chip guard pattern 135G. Each of the dummy pattern 127D and the buffer pattern 127B1 may include a nitride layer, a silicon layer, an oxynitride layer, or a silicon oxide layer.

Although not illustrated, a peripheral circuit structure forming the logic circuit and an interconnection structure electrically connected to the peripheral circuit structure may be disposed between a vertical level at which the source structure 110A is disposed and the substrate 101. The first conductive contact structure 125PC may extend to directly contact the substrate 101 or may be coupled to the substrate 101 via the interconnection structure.

A source level stacked body 110B may be disposed over one or both of the peripheral circuit contact region PCR and the chip guard region GR of the substrate 101. The source level stacked body 110B may be positioned at a vertical level where the source structure 110A is disposed. In an embodiment, the first doped semiconductor layer 111 and the second doped semiconductor layer 119 of the source structure 110A may extend over at least one of the peripheral circuit contact region PCR and the chip guard region GR of the substrate 101 to form the source level stacked body 110B. The source level stacked body 110B may further include a sacrificial structure 110S between the first doped semiconductor layer 111 and the second doped semiconductor layer 119. The sacrificial structure 110S may include a first passivation layer 113, a source sacrificial layer 115, and a second passivation layer 117 that are stacked over the first doped semiconductor layer 111. The first passivation layer 113 and the second passivation layer 117 may include a material having an etch selectivity with respect to the first doped semiconductor layer 111 and the second doped semiconductor layer 119. In an embodiment, the first passivation layer 113 and the second passivation layer 117 may include an oxide layer. The source sacrificial layer 115 may include a material having an etch selectivity with respect to the first passivation layer 113 and the second passivation layer 117. In an embodiment, the source sacrificial layer 115 may include an undoped silicon layer, a nitride layer, etc.

The source level stacked body 110B may be penetrated by a lower insulating layer 121. The lower insulating layer 121 may extend to cover a top surface of each of the source structure 110A and the source level stacked body 110B. The lower insulating layer 121 may be formed of an insulating material, such as an oxide layer. Each of the first conductive contact structure 125PC and the first conductive chip guard pattern 125G may penetrate through a corresponding lower insulating layer 121. Each of the dummy pattern 127D and the buffer pattern 127B1 may be disposed in the lower insulating layer 121.

A dummy stacked body 130 may be disposed over the source level stacked body 110B. The dummy stacked body 130 may be located at a vertical level where the gate stacked body 150 is disposed. In an embodiment, the plurality of interlayer insulating layers 131 of the gate stacked body 150 may extend over at least one of the peripheral circuit contact region PCR and the chip guard region GR of the substrate 101 to form the dummy stacked body 130. The dummy stacked body 130 further includes a plurality of sacrificial insulating layers 133. The plurality of sacrificial insulating layers 133 are alternately stacked in a vertical direction with a plurality of dummy portions of the plurality of interlayer insulating layers 131 forming the dummy stacked body 130. The plurality of sacrificial insulating layers 133 may include an insulating material having an etch selectivity with respect to the plurality of interlayer insulating layers 131. In an embodiment, the plurality of interlayer insulating layers 131 may include a silicon oxide layer, and the plurality of sacrificial insulating layers 133 may include a silicon nitride layer. The dummy stacked body 130 may be penetrated by the second conductive contact structure 135PC and the second conductive chip guard pattern 135G.

The buffer layer constituting the dummy pattern 127D and the buffer pattern 127B1 may include a material having an etch selectivity with respect to the plurality of sacrificial insulating layers 133 and the plurality of interlayer insulating layers 131. In an embodiment, the nitride layer, the oxynitride layer, or the silicon oxide layer forming the buffer layer may have a higher density as compared to the plurality of sacrificial insulating layers 133 and the plurality of interlayer insulating layers 131. Embodiments of the present disclosure, however, are not limited thereto. In an embodiment, the nitride layer or the oxynitride layer forming the buffer layer may include a metal.

The first insulating layer 151, the second insulating layer 171, and the third insulating layer 175 may extend over the peripheral circuit contact region PCR and the chip guard region GR of the substrate 101. The third conductive contact structure 159PC and the contact level conductive chip guard pattern 159G may penetrate through the first insulating layer 151, the fourth conductive contact structure 173PC and the contact level conductive chip guard pattern 173G may penetrate through the second insulating layer 171, and the signal line 177CL and the bit line level conductive chip guard pattern 177G may penetrate through the third insulating layer 175. The contact level conductive chip guard patterns 159G and 173G and the bit line level conductive chip guard pattern 177G are shorter in the vertical direction as compared to the second conductive chip guard pattern 135G.

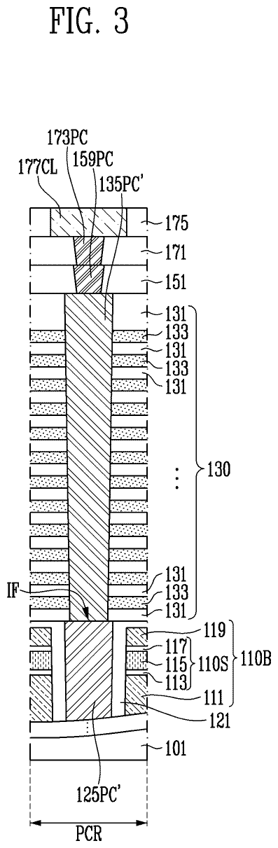

FIG. 3 is a sectional view illustrating a peripheral contact structure and a signal line according to an embodiment of the present disclosure.

Referring to FIG. 3, the peripheral contact structure may include a first conductive contact structure 125PC′, a second conductive contact structure 135PC′, a third conductive contact structure 159PC, and a fourth conductive contact structure 173PC, which are vertically arranged over the peripheral circuit contact region PCR of the substrate 101, and the signal line 177CL may be coupled to the fourth conductive contact structure 173PC. An interface IF between the first conductive contact structure 125PC′ and the second conductive contact structure 135PC′ may be at substantially the same vertical level as the top surface TS of the buffer layer constituting the buffer pattern 127B1 illustrated in FIG. 2B. Referring to FIG. 2B, the top surface TS of the buffer layer faces the second conductive chip guard pattern 135G.

Referring to FIG. 3, the third conductive contact structure 159PC, the fourth conductive contact structure 173PC, and the signal line 177CL may be configured in the same manner as described with reference to FIG. 2A. The first doped semiconductor layer 111, the sacrificial structure 110S, and the second doped semiconductor layer 119 of the source level stacked body 110B, the first passivation layer 113, the source sacrificial layer 115, and the second passivation layer 117 of the sacrificial structure 110S, the lower insulating layer 121, the plurality of interlayer insulating layers 131, and the plurality of sacrificial insulating layers 133 of the dummy stacked body 130, and the first, second, and third insulating layers 151, 171, and 175 may be configured in the same manner as described with reference to FIGS. 2A and 2B.

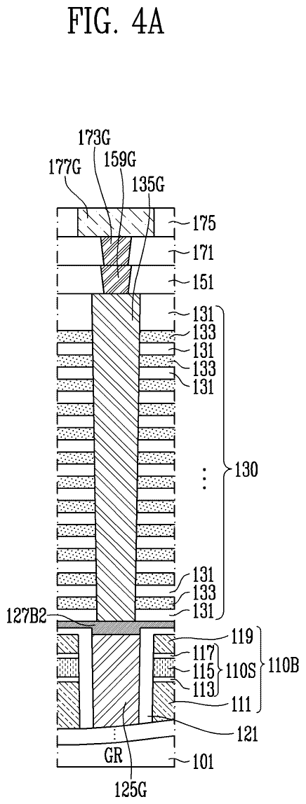

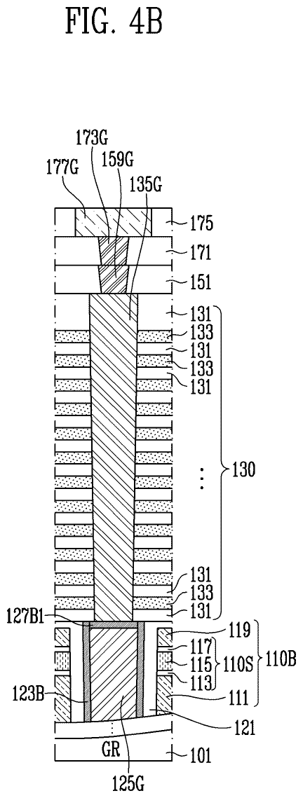

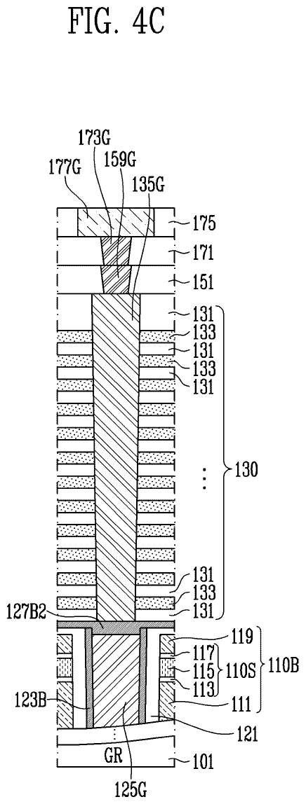

FIGS. 4A, 4B, and 4C are sectional views illustrating chip guards according to embodiments of the present disclosure.

Referring to FIGS. 4A, 4B, and 4C, each of the chip guards may include a first conductive chip guard pattern 125G, a second conductive chip guard pattern 135G, contact level conductive chip guard patterns 159G and 173G, and a bit line level conductive chip guard pattern 177G, which are vertically arranged over the chip guard region GR of the substrate 101 as described with reference to FIG. 2B. The first doped semiconductor layer 111, the sacrificial structure 110S, and the second doped semiconductor layer 119 of the source level stacked body 110B, the first passivation layer 113, the source sacrificial layer 115, the second passivation layer 117, and the lower insulating layer 121 of the sacrificial structure 110S, the plurality of interlayer insulating layers 131, and the plurality of sacrificial insulating layers 133 of the dummy stacked body 130, and the first, second, and third insulating layers 151, 171, and 175 may be configured in the same manner as described with reference to FIG. 2B.

Referring to FIGS. 4A and 4C, a buffer layer 127B2 may be disposed between the first conductive chip guard pattern 125G and the second conductive chip guard pattern 135G, and the buffer layer 127B2 may extend between the dummy stacked body 130 and the source level stacked body 110B. The buffer layer 127B2 may include a nitride layer, an oxynitride layer, or a silicon oxide layer. In an embodiment, the nitride layer, the oxynitride layer, or the silicon oxide layer may have a higher density as compared to the plurality of sacrificial insulating layers 133 and the plurality of interlayer insulating layers 131. In an embodiment, the nitride layer or the oxynitride layer may contain metal.

Referring to FIGS. 4B and 4C, a sidewall buffer pattern 123B may be formed on the sidewall of the first conductive chip guard pattern 125G. The sidewall buffer pattern 123B may be interposed between the lower insulating layer 121 and the first conductive chip guard pattern 125G. In an embodiment, the sidewall buffer pattern 123B may alleviate stress applied to the first conductive chip guard pattern 125G during the manufacturing process of the semiconductor device. The sidewall buffer pattern 123B may include a nitride layer or a silicon layer.

A plurality of conductive chip guard patterns 125G, 135G, 159G, and 177G illustrated in FIGS. 2B, 4A, 4B, and 4C may be formed using the process for forming the patterns of the integrated circuit disposed in the integrated circuit region ICR illustrated in FIG. 2A.

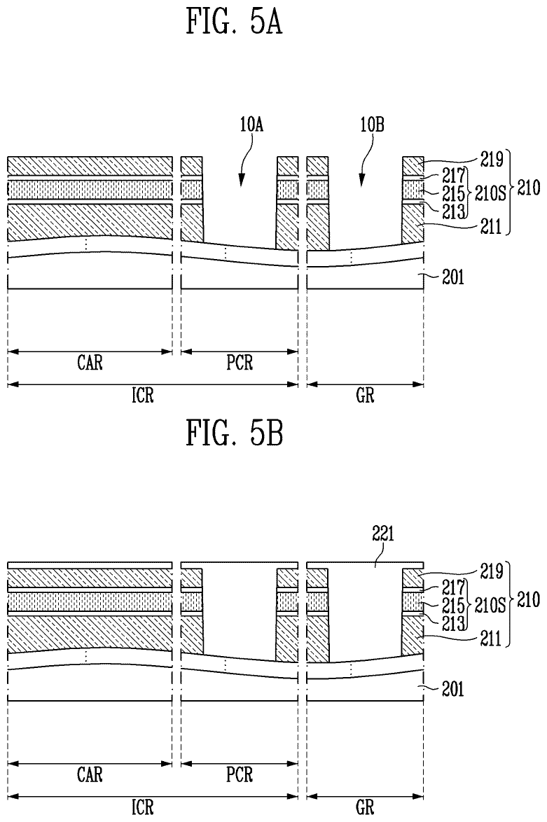

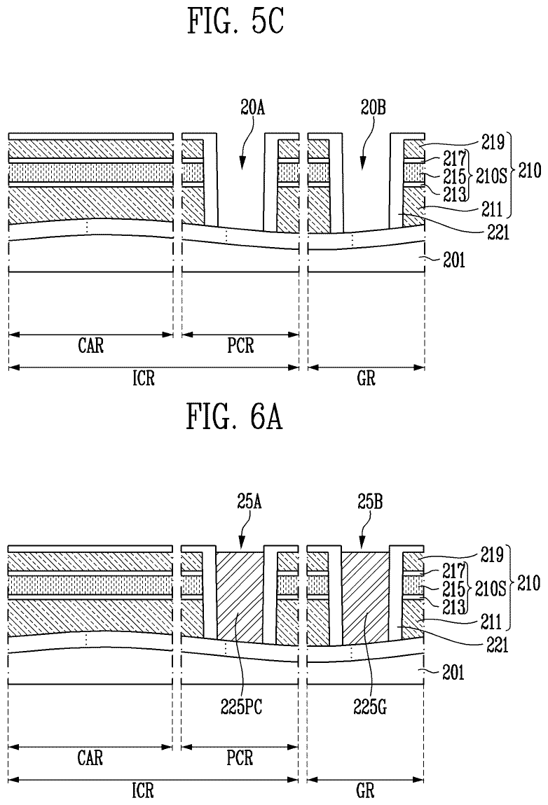

Hereinafter, a method of manufacturing a semiconductor device according to an embodiment of the present disclosure will be described with reference to FIGS. 5A to 5C, 6A, 6B, 7, 8A to 8I, 9, 10, 11A and 11B. The integrated circuit region ICR, the cell array region CAR, the peripheral circuit contact region PCR, and the chip guard region GR of the semiconductor substrate 201 illustrated in the drawings will be described with reference to FIGS. 1, 2A, and 2B.

FIGS. 5A, 5B, and 5C are sectional views illustrating a preliminary source stacked body and a lower insulating layer according to an embodiment of the present disclosure.

Referring to FIG. 5A, the preliminary source stacked body 210 may be formed over the substrate 201. The substrate 201 may include a monocrystalline semiconductor layer. In an embodiment, the substrate 201 may include a silicon wafer or a silicon substrate.

Although not illustrated in the drawing, the preliminary source stacked body 210 may be formed over a lower structure after forming the lower structure, such as an insulating layer, an etching stop layer, and a peripheral circuit structure constituting a logic circuit over the substrate 201. The preliminary source stacked body 210 may be disposed over the integrated circuit region ICR of the substrate 201, and may extend over the chip guard region GR. As in the source level stacked body 110B illustrated in FIGS. 2A and 2B, the preliminary source stacked body 210 may include a first doped semiconductor layer 211, a sacrificial structure 210S over the first doped semiconductor layer 211, and a second doped semiconductor layer 219 over the sacrificial structure 210S. As described with reference to FIGS. 2A and 2B, the sacrificial structure 210S may be formed as a stacked body including the first passivation layer 213, the source sacrificial layer 215, and the second passivation layer 217.

Subsequently, a first opening 10A and a second opening 10B may be formed to pass through the preliminary source stacked body 210 by an exposure process and an etching process using a first mask. The first opening 10A may pass through a portion of the preliminary source stacked body 210 overlapping the peripheral circuit contact region PCR of the substrate 201, and the second opening 10B may pass through another portion of the preliminary source stacked body 210 overlapping the chip guard region GR of the substrate 201.

Referring to FIG. 5B, a lower insulating layer 221 may be formed to fill the first opening 10A and the second opening 10B illustrated in FIG. 5A. The lower insulating layer 221 may extend to cover the top surface of the preliminary source stacked body 210.

Referring to FIG. 5C, a third opening 20A and a fourth opening 20B may be formed to pass through the lower insulating layer 221 by an exposure process and an etching process using a second mask. The third opening 20A may pass through a portion of the lower insulating layer 221 inside the first opening 10A illustrated in FIG. 5A, and the fourth opening 20B may pass through another portion of the lower insulating layer 221 inside the second opening 10B illustrated in FIG. 5A.

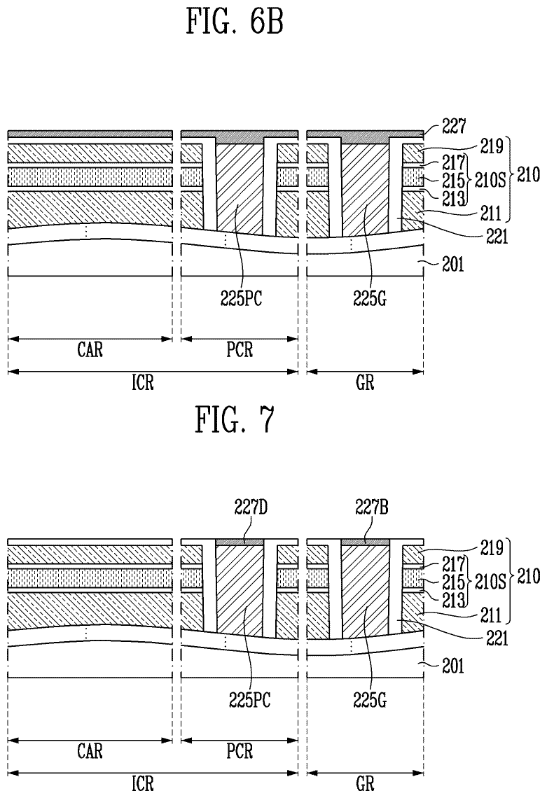

FIGS. 6A and 6B are sectional views illustrating a conductive penetration structure of a first group and a buffer layer according to an embodiment of the present disclosure.

Referring to FIG. 6A, after depositing a conductive material to fill the third opening 20A and the fourth opening 20B illustrated in FIG. 5C, the surface of the conductive material may be planarized to expose the lower insulating layer 221. Thus, the conductive material may be separated into a first conductive contact structure 225PC and a first conductive chip guard pattern 225G constituting the conductive penetration structure of the first group.

The deposition process of the conductive material may include a process of forming a metal barrier layer along the surfaces of the third opening 20A and the fourth opening 20B illustrated in FIG. 5C, and a process of forming a metal layer on the metal barrier layer.

A process of planarizing the surface of the conductive material may be performed to form a recess region on the conductive penetration structure of the first group. A first recess region 25A may be formed on the first conductive contact structure 225PC and a second recess region 25B may be formed on the first conductive chip guard pattern 225G by the planarization process of the conductive material.

Referring to FIG. 6B, a buffer layer 227 may be formed to fill the first recess region 25A and the second recess region 25B illustrated in FIG. 6A. The buffer layer 227 may extend to cover the lower insulating layer 221.

The buffer layer 227 may be formed using a high-density plasma chemical vapor deposition (HDPCVD) method. The buffer layer 227 may include a nitride layer or a silicon layer.

In an embodiment, when depositing the nitride layer using the HDPCVD method, a portion of the metal layer of each of the first conductive contact structure 225PC and the first conductive chip guard pattern 225G may undergo nitriding, and the nitride layer may be deposited over the upper portion of the lower insulating layer 221 and the upper portion of the nitrided metal layer. Because the nitride layer formed through the HDPCVD method may have a higher density than a nitride layer formed through the plasma enhanced chemical vapor deposition (PECVD) method, it may have an etch selectivity with respect to the nitride layer formed through the PECVD method.

FIG. 7 is a sectional view illustrating a dummy pattern and a buffer pattern of a buffer layer according to an embodiment of the present disclosure.

Referring to FIG. 7, by planarizing the buffer layer 227 illustrated in FIG. 6B using a Chemical Mechanical Polishing (CMP) method, the buffer layer 227 may be separated into a dummy pattern 227D and a buffer pattern 227B. The lower insulating layer 221 may be exposed by the planarization of the buffer layer.

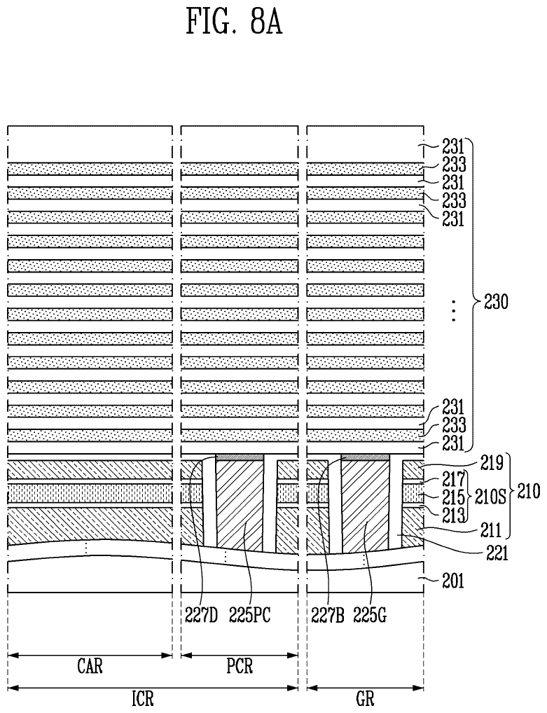

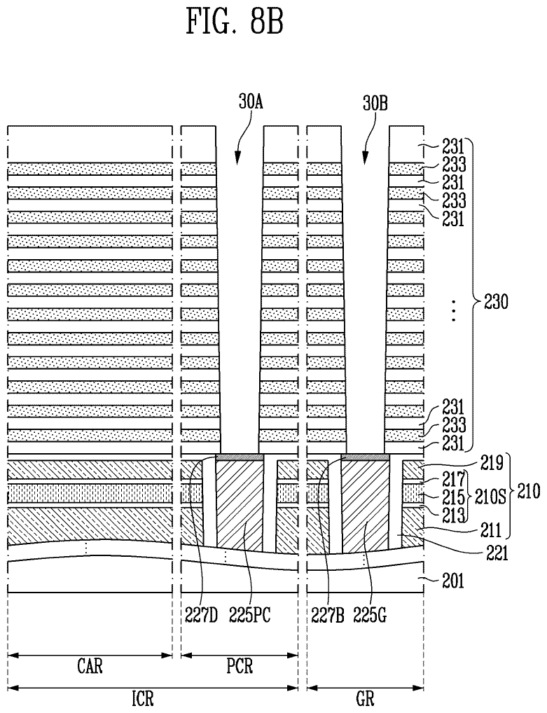

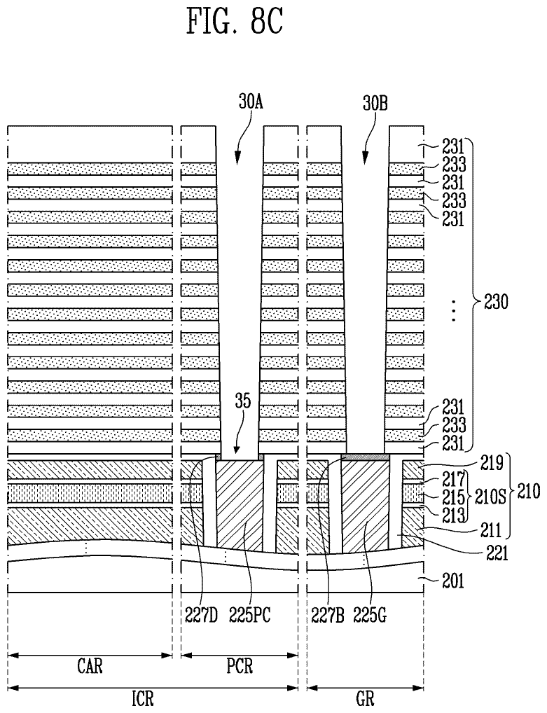

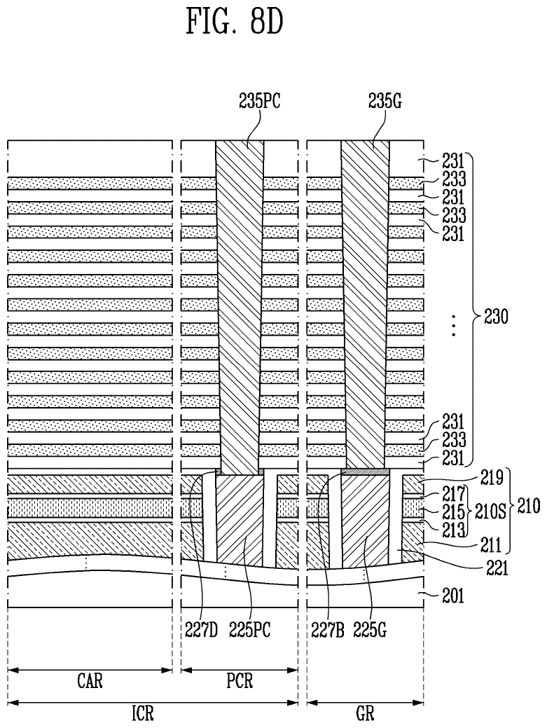

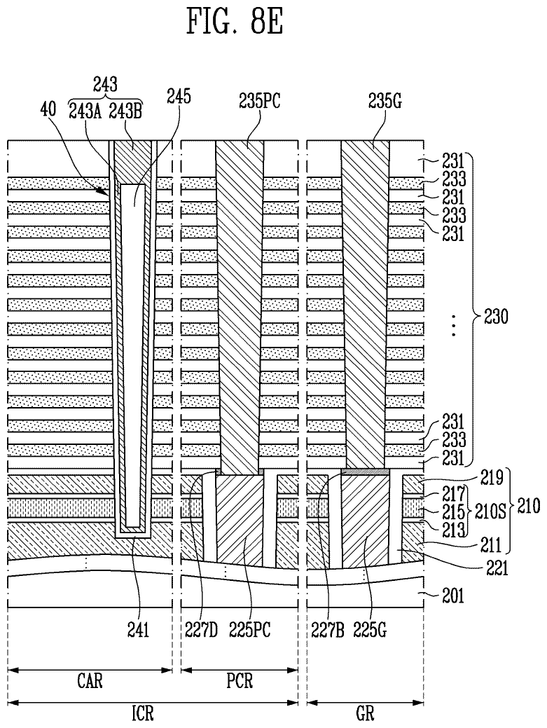

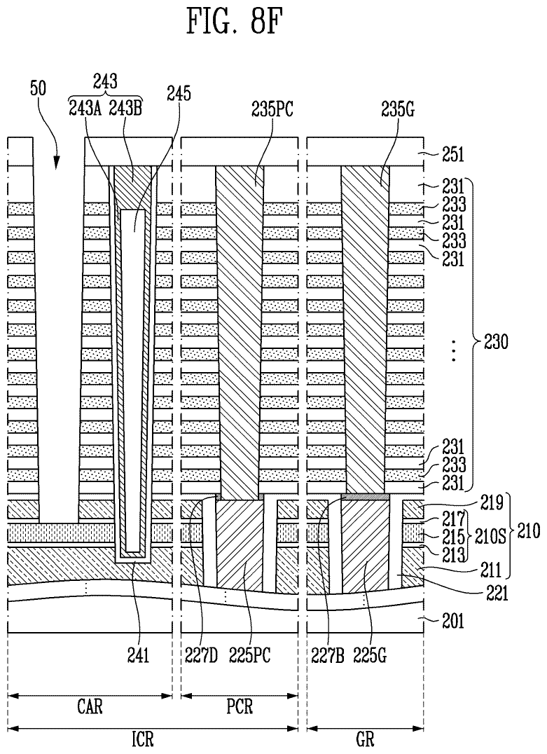

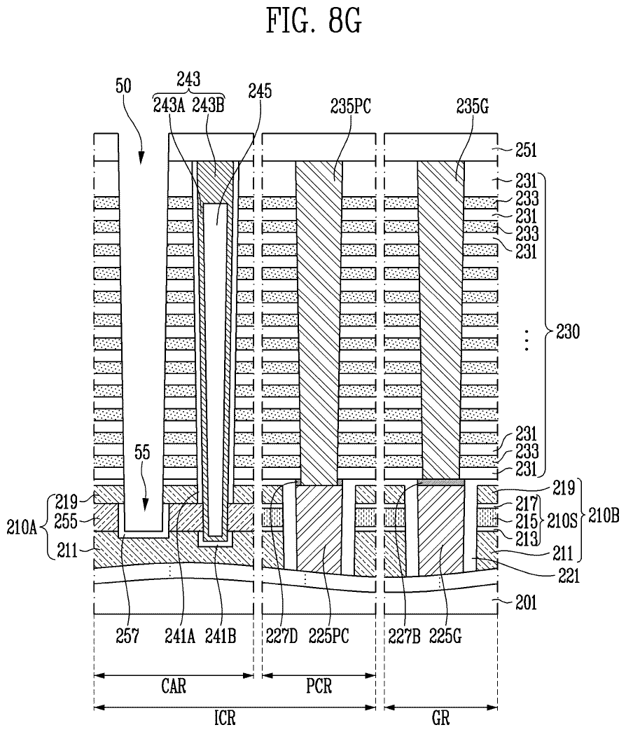

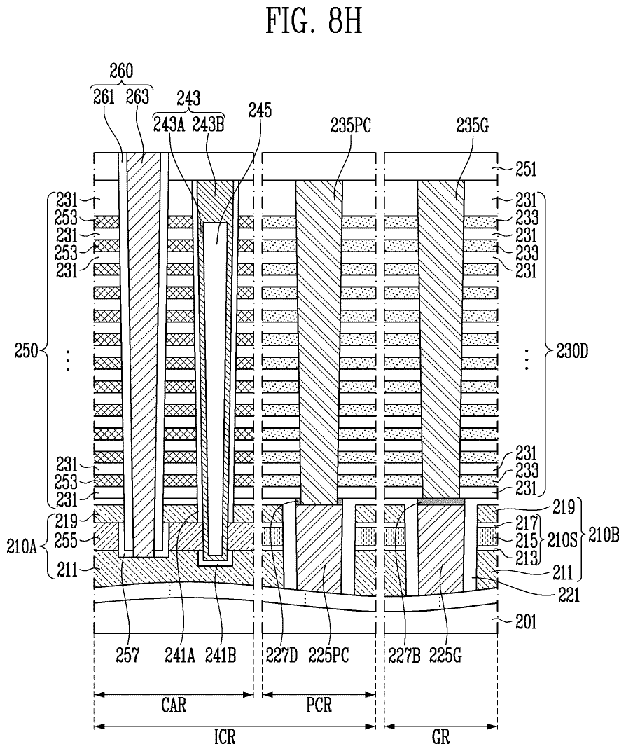

FIGS. 8A to 8I are sectional views illustrating a stacked body, a conductive penetration structure of a second group, a memory layer, a channel structure, a slit, a source structure, a gate stacked body, a vertical structure, and a conductive penetration structure of a third group according to an embodiment of the present disclosure.

Referring to FIG. 8A, a plurality of first material layers 231 and a plurality of second material layers 233 may be stacked over the substrate 201 in the vertical direction. The plurality of first material layers 231 may be alternately disposed with the plurality of second material layers 233 in the vertical direction. Thus, a stacked body 230 may be formed to cover the lower insulating layer 221, the dummy pattern 227D, and the buffer pattern 227B. A plurality of first material layers 231 and a plurality of second material layers 233 may be formed using the PECVD method.

The plurality of second material layers 233 may include a material having an etch selectivity with respect to the plurality of first material layers 231. In an embodiment, the plurality of first material layers 231 may be the plurality of interlayer insulating layers 131 described with reference to FIGS. 2A and 2B and the layers may include silicon oxide. The plurality of second material layers 233 may include silicon nitride layers. The silicon nitride layers may have an etch selectivity with respect to the nitride layer including metal.

Referring to FIG. 8B, a fifth opening 30A and a sixth opening 30B may be formed to pass through the stacked body 230 by an exposure process and an etching process using a third mask. The fifth opening 30A may pass through a portion of the stacked body 230 overlapping the peripheral circuit contact region PCR of the substrate 201, and the sixth opening 30B may pass through another portion of the stacked body 230 overlapping the chip guard region GR of the substrate 201. A dummy pattern 227D and a buffer pattern 227B may be exposed through the fifth opening 30A and the sixth opening 30B, respectively. During the etching process for forming the fifth opening 30A and the sixth opening 30B, the dummy pattern 227D and the buffer pattern 227B may serve as etching stop layers.

The etching process for forming the fifth opening 30A and the sixth opening 30B may be performed through plasma etching. Stress applied to the first conductive chip guard pattern 225G during plasma etching can be alleviated by the buffer pattern 227B.

Referring to FIG. 8C, the dummy pattern 227D may be selectively removed by the etching process targeting the fifth opening 30A. Thus, a seventh opening 35 may be formed through the dummy pattern 227D. The first conductive contact structure 225PC may be exposed through the seventh opening 35.

Referring to FIG. 8D, after depositing the conductive material to fill the fifth opening 30A, the sixth opening 30B, and the seventh opening 35 illustrated in FIG. 8C, the surface of the conductive material may be planarized. Thus, the conductive material may be separated into a second conductive contact structure 235PC and a second conductive chip guard pattern 235G constituting the conductive penetration structure of the second group.

The second conductive contact structure 235PC may fill the fifth opening 30A and the seventh opening 35 illustrated in FIG. 8C and may contact the first conductive contact structure 225PC. The second conductive chip guard pattern 235G may fill the sixth opening 30B illustrated in FIG. 8C and may be spaced apart from the first conductive chip guard pattern 225G by the buffer pattern 227B. Thus, the propagation of a crack from one of the first conductive chip guard pattern 225G and the second conductive chip guard pattern 235G to the other chip guard pattern may be prevented, mitigated, or reduced through the buffer pattern 227B.

Referring to FIG. 8E, a seventh opening 40 may be formed by an exposure process and an etching process using a fourth mask. The seventh opening 40 may pass through the stacked body 230 and the lower insulating layer 221 over the cell array region CAR of the substrate 201. The seventh opening 40 may extend into the first doped semiconductor layer 211 of the preliminary source stacked body 210.

Subsequently, a process of forming the memory layer 241 along the surface of the seventh opening 40, a process of forming the first semiconductor layer along the surface of the memory layer 241, and a process of filling a central region of the seventh opening 40 opened by the first semiconductor layer with the core insulating layer 245 and the second semiconductor layer may be performed. After the conductive impurities are implanted into the second semiconductor layer, an annealing process may be performed to activate the conductive impurities. The first semiconductor layer and the second semiconductor layer may form a channel structure 243. A portion of the first semiconductor layer interposed between the memory layer 241 and the core insulating layer 245 may form a channel portion 243A of the channel structure 243, and a remaining portion of the first semiconductor layer and the second semiconductor layer may form a capping portion 243B of the channel structure 243.

Referring to FIG. 8F, a first insulating layer 251 may be formed to cover the stacked body 230, the second conductive contact structure 235PC, the second conductive chip guard pattern 235G, and the channel structure 243.

Thereafter, a slit 50 may be formed by an exposure process and an etching process using a fifth mask. The slit 50 may overlap the cell array region CAR of the substrate 201, and may penetrate through the first insulating layer 251, the stacked body 230, and the lower insulating layer 221. The slit 50 may extend to penetrate through the second doped semiconductor layer 219 and the second passivation layer 217 of the preliminary source stacked body 210. Thus, the source sacrificial layer 215 may be exposed by the slit 50.

Referring to FIG. 8G, after a portion of the source sacrificial layer 215 illustrated in FIG. 8F is selectively removed through the slit 50, a portion of the memory layer exposed through a region where the source sacrificial layer is removed may be removed. Thus, the memory layer 241 illustrated in FIG. 8F may be separated into a first memory pattern 241A and a second memory pattern 241B, and a portion of the channel structure 243 may be exposed. While a portion of the memory layer is removed, a portion of the first passivation layer 213 and a portion of the second passivation layer 217 overlapping the cell array region CAR of the substrate 201 may be removed.

Subsequently, a region from which the first passivation layer 213, the source sacrificial layer 215, and the second passivation layer 217 were removed may be filled with a third doped semiconductor layer 255. Thereafter, a portion of the third doped semiconductor layer 255 may be etched so that the third doped semiconductor layer 255 may be removed from the inside of the slit 50.

While a portion of the third doped semiconductor layer 255 is etched, a trench 55 may be formed to penetrate through the third doped semiconductor layer 255. The trench 55 may overlap the slit 50. The trench 55 may be formed wider than the slit 50, and both ends of the trench 55 may overlap a bottom surface of the second doped semiconductor layer 219. The trench 55 may extend into the first doped semiconductor layer 211.

The third doped semiconductor layer 255 may contact the first doped semiconductor layer 211 and the second doped semiconductor layer 219. The first doped semiconductor layer 211, the second doped semiconductor layer 219, and the third doped semiconductor layer 255, which are coupled to each other, may form a source structure 210A. The preliminary source stacked body may form a source level stacked body 210B over the peripheral circuit contact region PCR and the chip guard region GR of the substrate 201.

The third doped semiconductor layer 255 may include n-type impurities as the majority carrier. After forming the source structure 210A, a passivation layer 257 may be formed along the surface of the trench 55.

Referring to FIG. 8H, a portion of the plurality of second material layers 233 disposed over the cell array region CAR of the substrate 201 may be replaced with a plurality of conductive layers 253 through the slit 50 illustrated in FIG. 8G. Thus, a gate stacked body 250 including the plurality of first material layers 231 and the plurality of conductive layers 253 may be formed. Another portion of the plurality of first material layers 231 over the peripheral circuit contact region PCR and the chip guard region GR of the substrate 201 and the plurality of second material layers 233 may form a dummy stacked body 230D.

Subsequently, a vertical structure 260 may be formed to fill the slit 50 and the trench 55 illustrated in FIG. 8G. The vertical structure 260 may include a sidewall insulating layer 261 and a core pattern 263. The sidewall insulating layer 261 may be disposed on the sidewall of the gate stacked body 250 and may extend to cover the passivation layer 257. The core pattern 263 may be formed of various materials, such as a metal or a semiconductor material.

Referring to FIG. 8I, a subsequent process, such as a process of forming the conductive penetration structure of the third group penetrating through the first insulating layer 251, may be performed. The conductive penetration structure of the third group may include a conductive via structure 259BC coupled to the channel structure 243, a third conductive contact structure 259PC coupled to the second conductive contact structure 235PC, and a contact level conductive chip guard pattern 259G coupled to the second conductive chip guard pattern 235G.

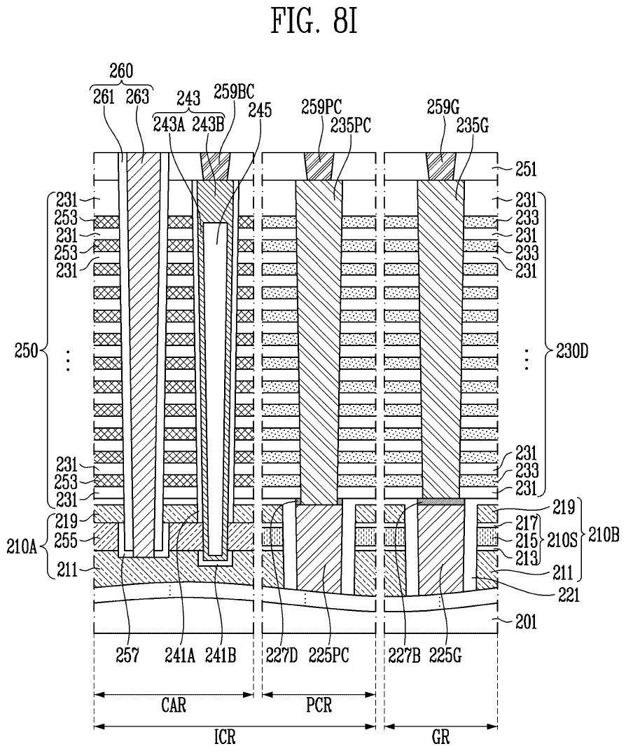

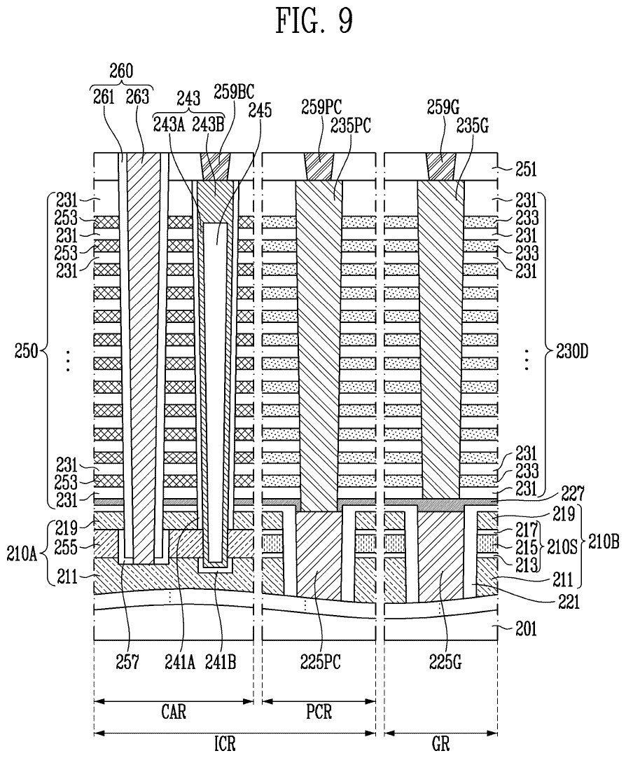

FIG. 9 is a sectional view illustrating a buffer layer, a first conductive chip guard pattern, and a second conductive chip guard pattern according to an embodiment of the present disclosure.

Referring to FIG. 9, the first doped semiconductor layer 211, the first passivation layer 213, the source sacrificial layer 215, and the second passivation layer 217 of the sacrificial structure 210S, the second doped semiconductor layer 219, and the lower insulating layer 221 may be formed over the substrate 201 using the processes described with reference to FIGS. 5A to 5C. Subsequently, the first conductive contact structure 225PG, the first conductive chip guard pattern 225G, and the buffer layer 227 may be formed using the processes described with reference to FIGS. 6A and 6B. At this time, the buffer layer 227 may be a nitride layer formed through the HDPCVD method.

The plurality of first material layers 231 and the plurality of second material layers 233 may be stacked over the buffer layer 227 in a state where the buffer layer 227 formed of the nitride layer remains to cover the top surface of the lower insulating layer 221. The plurality of first material layers 231 may be alternately disposed with the plurality of second material layers 233.

Subsequently, the processes described with reference to FIGS. 8A to 8I may be performed. Thereby, the first memory pattern 241A, the second memory pattern 241B, the channel portion 243A and the capping portion 243B of the channel structure 243, the core insulating layer 245, the first insulating layer 251, the first doped semiconductor layer 211, the second doped semiconductor layer 219, and the third doped semiconductor layer 255 of the source structure 210A, the passivation layer 257, the plurality of first material layers 231 and the plurality of conductive layers 253 of the gate stacked body 250, the sidewall insulating layer 261 and the core pattern 263 of the vertical structure 260, the conductive via structure 259BC, the third conductive contact structure 259PC, and the contact level conductive chip guard pattern 259G may be formed. The first doped semiconductor layer 211, the sacrificial structure 210S, and the second doped semiconductor layer 219 disposed over the peripheral circuit contact region PCR and the chip guard region GR of the substrate 201 may remain as the source level stacked body 210B. The plurality of first material layers 231 and the plurality of second material layers 233 disposed over the peripheral circuit contact region PCR and the chip guard region GR of the substrate 201 may remain as the dummy stacked body 230D.

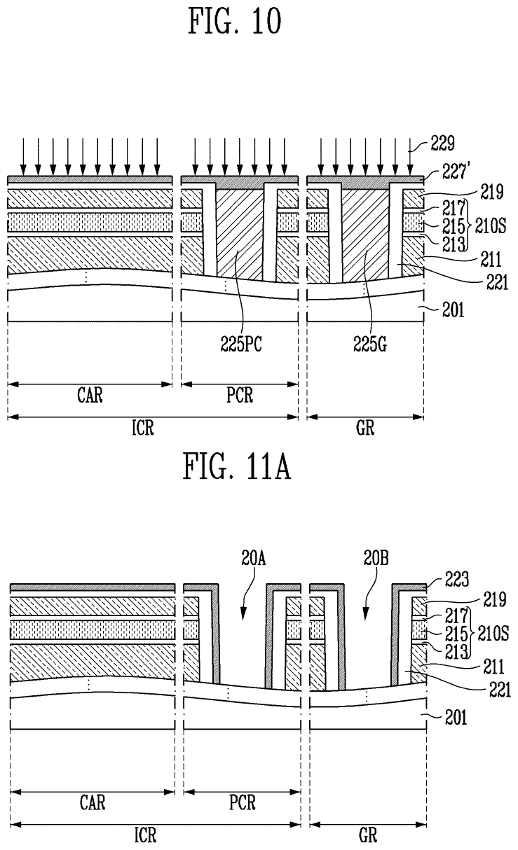

FIG. 10 is a sectional view illustrating a buffer layer according to an embodiment of the present disclosure.

Referring to FIG. 10, the first doped semiconductor layer 211, the first passivation layer 213, the source sacrificial layer 215, and the second passivation layer 217 of the sacrificial structure 210S, the second doped semiconductor layer 219, and the lower insulating layer 221 may be formed over the substrate 201 using the processes described with reference to FIGS. 5A to 5C. Subsequently, the first conductive contact structure 225PC, the first conductive chip guard pattern 225G, and the buffer layer may be formed using the processes described with reference to FIGS. 6A and 6B.

As described with reference to FIG. 6B, the buffer layer may be formed through the HDPCVD method and may extend to cover the lower insulating layer 221. Subsequently, the buffer layer may be oxidized using oxidizing gas 229. Thus, an oxidation buffer layer 227′ may be formed. The oxidation buffer layer 227′ may include an oxynitride layer or a silicon oxide layer.

Subsequently, the processes described with reference to FIGS. 7 and 8A to 8I may be performed, or the process described with reference to FIG. 7 may be omitted and the processes described with reference to FIGS. 8A to 8I may be performed.

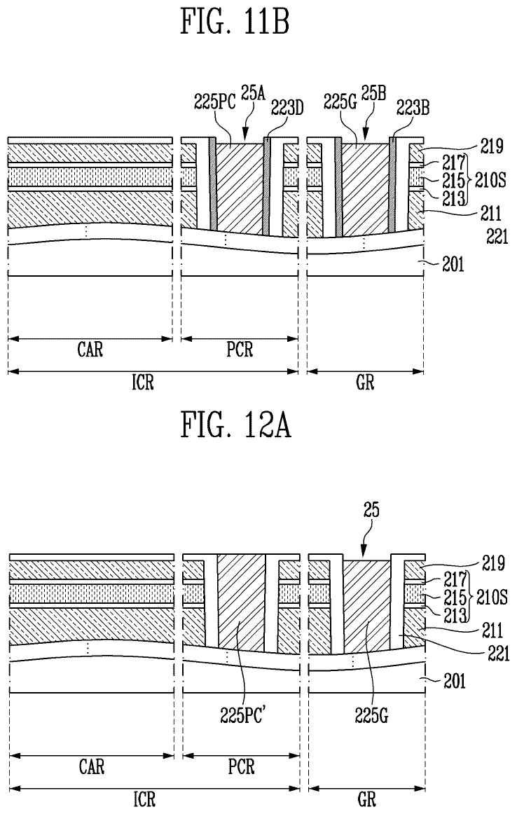

FIGS. 11A and 11B are sectional views illustrating a sidewall buffer pattern and a conductive penetration structure of a first group according to an embodiment of the present disclosure.

Referring to FIG. 11A, the first doped semiconductor layer 211, the first passivation layer 213, the source sacrificial layer 215, and the second passivation layer 217 of the sacrificial structure 210S, the second doped semiconductor layer 219, and the lower insulating layer 221 may be formed over the substrate 201 using the processes described with reference to FIGS. 5A to 5C.

Subsequently, an auxiliary layer 223 may be formed to cover the sidewall of each of the third opening 20A and the fourth opening 20B and extend over the lower insulating layer 221. The auxiliary layer 223 may include a nitride layer or a silicon layer.

Referring to FIG. 11B, after depositing a conductive material over the auxiliary layer 223 illustrated in FIG. 11A to fill the third opening 20A and the fourth opening 20B illustrated in FIG. 11A, the surfaces of the auxiliary layer and the conductive material may be planarized to expose the lower insulating layer 221. Thus, the conductive material may be separated into the first conductive contact structure 225PC and the first conductive chip guard pattern 225G constituting the conductive penetration structure of the first group. The auxiliary layer may be separated into a sidewall dummy pattern 223D between the first conductive contact structure 225PC and the lower insulating layer 221 and a sidewall buffer pattern 223B between the first conductive chip guard pattern 225G and the lower insulating layer 221.

As described with reference to FIG. 6A, a planarization process may be performed so that a first recess region 25A may be formed on the first conductive contact structure 225PC and a second recess region 25B may be formed on the first conductive chip guard pattern 225G.

Subsequently, the processes described with reference to FIGS. 6B, 7, and 8A to 8I may be performed, the processes described with reference to FIGS. 6B and 9 may be performed, or the processes described with reference to FIGS. 6B and 10 may be performed. The sidewall buffer pattern 223B may alleviate stress applied to the first conductive chip guard pattern 225G illustrated in FIG. 8B during the etching process for forming the sixth opening 30B illustrated in FIG. 8B.

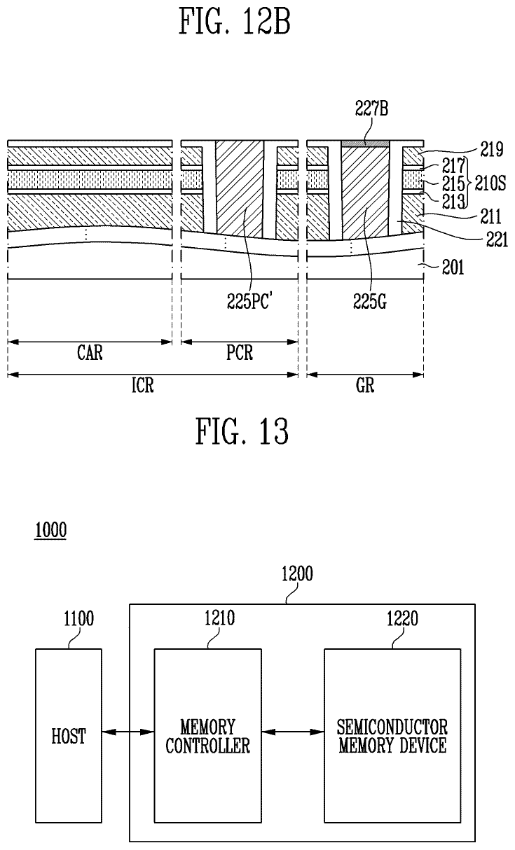

FIGS. 12A and 12B are sectional views illustrating a conductive penetration structure of a first group and a buffer pattern according to an embodiment of the present disclosure.

Referring to FIG. 12A, the first doped semiconductor layer 211, the first passivation layer 213, the source sacrificial layer 215, and the second passivation layer 217 of the sacrificial structure 210S, the second doped semiconductor layer 219, and the lower insulating layer 221 may be formed over the substrate 201 using the processes described with reference to FIGS. 5A to 5C.

Subsequently, after depositing a conductive material to fill the third opening 20A and the fourth opening 20B, the surfaces of the auxiliary layer and the conductive material may be planarized to expose the lower insulating layer 221. Thus, the conductive material may be separated into a first conductive contact structure 225PC′ and a preliminary first conductive chip guard pattern. The planarization process may be performed so that the surface of the preliminary first conductive chip guard pattern and the surface of the first conductive contact structure 225PC′ are positioned at substantially the same vertical level as the surface of the lower insulating layer 221.

Thereafter, by removing a portion of the preliminary first conductive chip guard pattern using an exposure process and an etching process using a mask, a recess region 25 and a first conductive chip guard pattern 225G may be formed. The first conductive chip guard pattern 225G and the first conductive contact structure 225PC′ may constitute the conductive penetration structure of the first group.

Before forming the conductive material for the conductive penetration structure of the first group described above, the process of forming the auxiliary layer 223 described with reference to FIG. 11A may be performed.

Referring to FIG. 12B, the buffer pattern 227B may be formed inside the recess region 25 illustrated in FIG. 12A, using the processes described with reference to FIGS. 6B and 7. Subsequently, the processes described with reference to FIGS. 8A to 8I may be performed. Embodiments of the present disclosure are not limited thereto. In an embodiment, as illustrated in FIG. 12A, after the recess region 25 is formed, the processes described with reference to FIGS. 6B and 9 may be performed, or the processes described with reference to FIGS. 6B and 10 may be performed.

FIG. 13 is a block diagram illustrating an electronic system according to an embodiment of the present disclosure.

Referring to FIG. 13, an electronic system 1000 may be a computing system, a medical device, a communication device, a wearable device, a memory system, etc. The electronic system 1000 may include a host 1100 and a storage device 1200.

The host 1100 may store data in the storage device 1200 or read data stored in the storage device 1200 using an interface. The interface may include one or more of a Double Data Rate (DDR) interface, an Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics (IDE) interface, a Firewire interface, a Universal Flash Storage (UFS) interface, and a Nonvolatile Memory express (NVMe) interface.

The storage device 1200 may include a memory controller 1210 and a semiconductor memory device 1220. According to different embodiments, the storage device 1200 may be a solid-state drive (SSD), a Universal Serial Bus (USB) memory, etc.

The memory controller 1210 may store data in the semiconductor memory device 1220 or read stored data from the semiconductor memory device 1220 under the control of the host 1100.

The semiconductor memory device 1220 may include one or more memory chips. The semiconductor memory device 1220 may store data or output stored data under the control of the memory controller 1210.

The semiconductor memory device 1220 may be a non-volatile memory device. The semiconductor memory device 1220 may include a first conductive chip guard pattern and a second conductive chip guard pattern disposed over a chip guard region of a substrate with a buffer layer disposed between the first and second conductive chip guard patterns.

According to an embodiment of the present disclosure, a buffer layer is disposed between first and second conductive chip guard patterns that are vertically overlapped, which may alleviate stress applied to the first conductive chip guard pattern during an etching process for an opening in which the second conductive chip guard pattern is disposed, through the buffer layer. Therefore, cracks in the first conductive chip guard pattern may be reduced, mitigated, or prevented, thereby improving structural stability and the stability of a manufacturing process of a semiconductor device.

What is claimed is:

1. A semiconductor device, comprising:
a substrate;
an integrated circuit over an integrated circuit region of the substrate;
a first conductive chip guard pattern over a chip guard region of the substrate, wherein the integrated circuit region is enclosed by the chip guard region;
a second conductive chip guard pattern over the first conductive chip guard pattern; and
a buffer layer between the first conductive chip guard pattern and the second conductive chip guard pattern.

2. The semiconductor device according to claim 1, wherein the second conductive chip guard pattern is longer in a vertical direction over the substrate than the first conductive chip guard pattern.

3. The semiconductor device according to claim 1, wherein:
each of the first conductive chip guard pattern and the second conductive chip guard pattern comprises metal, and
the buffer layer comprises a nitride layer, a silicon layer, an oxynitride layer, or a silicon oxide layer.

4. The semiconductor device according to claim 1, further comprising:
a memory cell array disposed over the integrated circuit region of the substrate.

5. The semiconductor device according to claim 4, further comprising:
a source structure over the integrated circuit region of the substrate, the source structure electrically connected to the memory cell array; and
a bit line spaced apart from the source structure in a vertical direction over the substrate, the bit line electrically connected to the memory cell array,
wherein the memory cell array comprises:
a channel structure coupled to the source structure and extending toward the bit line;
a plurality of conductive layers spaced apart from each other in the vertical direction between the source structure and the bit line, the channel structure extending through the plurality of conductive layers in the vertical direction; and
a memory layer between the plurality of conductive layers and the channel structure.

6. The semiconductor device according to claim 5, further comprising:
a bit line level conductive chip guard pattern over the chip guard region of the substrate,
wherein the first conductive chip guard pattern and the source structure are at a same vertical level, and
wherein the second conductive chip guard pattern is between the bit line level conductive chip guard pattern and the first conductive chip guard pattern.

7. The semiconductor device according to claim 6, further comprising:
at least one contact level conductive chip guard pattern between the second conductive chip guard pattern and the bit line level conductive chip guard pattern.

8. The semiconductor device according to claim 1, further comprising:
a sidewall buffer pattern on a sidewall of the first conductive chip guard pattern.

9. The semiconductor device according to claim 8, wherein the sidewall buffer pattern comprises a nitride layer or a silicon layer.

10. A semiconductor device, comprising:
a substrate;
a source structure over a cell array region of the substrate;
a channel structure extending from the source structure in a vertical direction over the cell array region of the substrate;
a gate stacked body including a plurality of interlayer insulating layers and a plurality of conductive layers alternately stacked over the source structure, the channel structure extending through the gate stacked body in the vertical direction;
a first conductive chip guard pattern over a chip guard region of the substrate, wherein the first conductive chip guard pattern and the source structure are at a same vertical level, wherein the chip guard region encloses an integrated circuit region of the substrate, and wherein the integrated circuit region includes the cell array region and a peripheral circuit region of the substrate;
a second conductive chip guard pattern over the first conductive chip guard pattern, wherein the second conductive chip guard pattern and the gate stacked body are at the same vertical level; and
a buffer layer between the first conductive chip guard pattern and the second conductive chip guard pattern.

11. The semiconductor device according to claim 10, wherein:
the source structure comprises:
a first doped semiconductor layer over the substrate;
a second doped semiconductor layer over the first doped semiconductor layer; and
a third doped semiconductor layer between the first doped semiconductor layer and the second doped semiconductor layer,
wherein the channel structure penetrates through the second doped semiconductor layer and extends into the first doped semiconductor layer, and
wherein the third doped semiconductor layer contacts the channel structure.

12. The semiconductor device according to claim 10, further comprising:
a source level stacked body over the chip guard region of the substrate; and
a lower insulating layer penetrating through the source level stacked body,
wherein the first conductive chip guard pattern penetrates through the lower insulating layer.

13. The semiconductor device according to claim 12, wherein the source level stacked body comprises:
a first doped semiconductor layer over the substrate;
a second doped semiconductor layer over the first doped semiconductor layer; and
a sacrificial structure between the first doped semiconductor layer and the second doped semiconductor layer.

14. The semiconductor device according to claim 12, further comprising:
a dummy stacked body over the source level stacked body,
wherein the dummy stacked body comprises a plurality of dummy portions of the plurality of interlayer insulating layers extending over the chip guard region, and a plurality of sacrificial insulating layers stacked alternately with the plurality of dummy portions in the vertical direction, and
wherein the second conductive chip guard pattern penetrates through the dummy stacked body.

15. The semiconductor device according to claim 14, wherein the buffer layer comprises a material having an etch selectivity with respect to the plurality of interlayer insulating layers and the plurality of sacrificial insulating layers.

16. The semiconductor device according to claim 14, wherein the buffer layer comprises a nitride layer, a silicon layer, an oxynitride layer, or a silicon oxide layer.

17. The semiconductor device according to claim 16, wherein the buffer layer extends between the dummy stacked body and the source level stacked body.

18. The semiconductor device according to claim 10, further comprising:
a sidewall buffer pattern on a sidewall of the first conductive chip guard pattern.

19. The semiconductor device according to claim 18, wherein the sidewall buffer pattern comprises a nitride layer or a silicon layer.

20. The semiconductor device according to claim 10, further comprising:
a first conductive contact structure over a peripheral circuit contact region of the substrate, wherein the first conductive contact structure and the first conductive chip guard pattern are at a same vertical level; and
a second conductive contact structure over the first conductive contact structure, wherein the second conductive contact structure and the second conductive chip guard pattern are at a same vertical level.

21. The semiconductor device according to claim 20, further comprising:
a dummy pattern over the first conductive contact structure, the dummy pattern enclosing a sidewall of the second conductive contact structure, and the dummy pattern comprising the same material as the buffer layer.

22. The semiconductor device according to claim 20, wherein an interface between the first conductive contact structure and the second conductive contact structure is at substantially the same vertical level as a top surface of the buffer layer facing the second conductive chip guard pattern.
